(19) United States
(12) Patent Application Publication
(10) Pub. No.: US 2025/0149466 A1
(43) Pub. Date: May 8, 2025

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Jaesic Lee, Suwon-si (KR)

(21) Appl. No.: 18/897,220

(22) Filed: Sep. 26, 2024

(30) Foreign Application Priority Data
Nov. 6, 2023 (KR) 10-2023-0152106

(51) Int. Cl. H01L 23/00; H01L 23/15; H01L 23/31; H01L 23/367; H01L 23/498; H01L 25/10

(52) U.S. Cl. CPC H01L 23/562; H01L 23/3675; H01L 23/49827; H01L 25/105; H01L 23/15; H01L 23/3185; H01L 23/49822; H01L 24/20; H01L 2224/2101; H01L 2225/1041

(57) ABSTRACT

A semiconductor package includes a lower redistribution wiring layer including first redistribution wirings, a semiconductor chip on the lower redistribution wiring layer, a core substrate on the lower redistribution wiring layer, the core substrate including a substrate having a cavity to accommodate the semiconductor chip, a plurality of through vias that extend into the substrate and electrically connect to ones of the first redistribution wirings, and a shielding structure that extends into the substrate and extends along an edge of the substrate, a sealing member in a gap between an inner wall of the cavity of the substrate and the semiconductor chip, and an upper redistribution wiring layer on the core substrate and including second redistribution wirings that are electrically connected to ones of the plurality of through vias.

### PRIORITY STATEMENT

This application claims priority under 35 U.S.C. § 119 to Korean Patent Application No. 10-2023-0152106, filed on Nov. 6, 2023 in the Korean Intellectual Property Office (KIPO), the contents of which are herein incorporated by reference in their entirety.

### BACKGROUND

Example embodiments relate to a semiconductor package and a method of manufacturing the semiconductor package. More particularly, example embodiments relate to a fan out package and a method of manufacturing the same.

In manufacturing a fan out package, a molding member may be formed on a lower redistribution wiring layer to cover or overlap copper posts and a semiconductor chip, and then an upper redistribution wiring layer may be formed on the molding member. There may be a problem that the heat dissipation performance of dissipating heat from the semiconductor chip is reduced due to the molding member. In addition, in the manufacturing process of the fan out package, there are many processes to turn over intermediate structures, making the process complicated and increasing the time required.

### SUMMARY

Example embodiments provide a semiconductor package including a structure that has improved heat dissipation characteristics and is able to simplify a manufacturing process.

Example embodiments provide a method of manufacturing the semiconductor package.

According to example embodiments, a semiconductor package includes a lower redistribution wiring layer including first redistribution wirings, a semiconductor chip on the lower redistribution wiring layer, a core substrate on the lower redistribution wiring layer, the core substrate including a substrate having a cavity to accommodate the semiconductor chip, a plurality of through vias that extend into the substrate and electrically connect to ones of the first redistribution wirings, and a shielding structure that extends into the substrate and extending along an edge of the substrate, a sealing member in a gap between an inner wall of the cavity of the substrate and the semiconductor chip, and an upper redistribution wiring layer on the core substrate and including second redistribution wirings that are electrically connected to ones of the plurality of through vias.

According to example embodiments, a semiconductor package includes a core substrate having a first surface and a second surface opposite the first surface, the core substrate including a glass substrate having a cavity extending from the first surface to the second surface, a plurality of through vias that extend into the glass substrate, and a shielding structure that extends into the glass substrate and extending along an edge of the glass substrate, a semiconductor chip in the cavity of the core substrate, the semiconductor chip having chip pads provided on a front surface of the semiconductor chip, the chip pads being exposed from the first surface of the core substrate, a lower redistribution wiring layer covering the first surface of the core substrate and including first redistribution wirings electrically connected to the chip pads and the plurality of through vias, and an upper redistribution wiring layer covering the second surface of the core substrate and including second redistribution wirings electrically connected to the plurality of through vias.

According to example embodiments, a semiconductor package includes a lower redistribution wiring layer including first redistribution wirings, a core substrate on the lower redistribution wiring layer, the core substrate including a substrate having a cavity, a plurality of through vias that extend into the substrate and electrically connect to the first redistribution wirings, and a shielding structure that extends into the substrate and extends along an edge of the substrate, a semiconductor chip in the cavity of the core substrate on the lower redistribution wiring layer and having chip pads electrically connected to the first redistribution wirings, a sealing member in a gap between the semiconductor chip and an inner wall of the cavity of the substrate, and an upper redistribution wiring layer on the core substrate and including second redistribution wirings electrically connected to the plurality of through vias.

According to example embodiments, a semiconductor package as a fan out package may include a lower redistribution wiring layer, a semiconductor chip on the lower redistribution wiring layer, a core substrate surrounding the semiconductor chip on an upper surface of the lower redistribution wiring layer, and an upper redistribution wiring layer on an upper surface of the core substrate. The core substrate may include a plurality of through vias that extend into a glass substrate and a shielding structure that extends into the glass substrate and extends along an edge of the glass substrate.

The shielding structure including a metal material may extend along the edge of the glass substrate and may function as a heat spreader that dissipates heat from the semiconductor chip in a horizontal direction, to thereby improve heat dissipation characteristics. Further, the shielding structure including rounded corner portions that may reduce the brittleness of the glass substrate and reinforce its brittleness.

In addition, the core substrate may be bonded to the upper redistribution wiring layer by hybrid bonding and then the lower redistribution wiring layer may be formed on the core substrate to form the semiconductor package. Accordingly, a manufacturing process may be simplified and the number of processes that involve turning over intermediate structures during the manufacturing process may be reduced to decrease the turn-around time (TAT).

### BRIEF DESCRIPTION OF THE DRAWINGS

Example embodiments will be more clearly understood from the following detailed description taken in conjunction with the accompanying drawings. FIGS. 1 to 28 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIG. 3 is a plan view illustrating an upper surface of a core substrate of FIG. 1.

FIG. 4 is an enlarged plan view illustrating portion ‘C’ in FIG. 3.

FIGS. 5 to 21 are views illustrating a method of manufacturing a semiconductor package in accordance with example embodiments.

FIG. 22 is a cross-sectional view illustrating a semiconductor package in accordance with example embodiments.

FIGS. 23 to 27 are cross-sectional views illustrating a method of manufacturing a semiconductor package in accordance with example embodiments.

FIG. 28 is a cross-sectional view illustrating a semiconductor package in accordance with example embodiments.

### DETAILED DESCRIPTION

Hereinafter, example embodiments will be explained in detail with reference to the accompanying drawings.

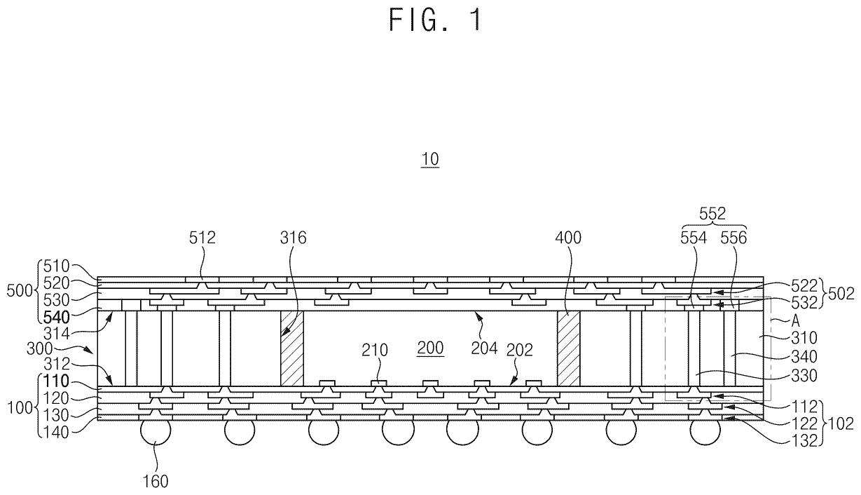

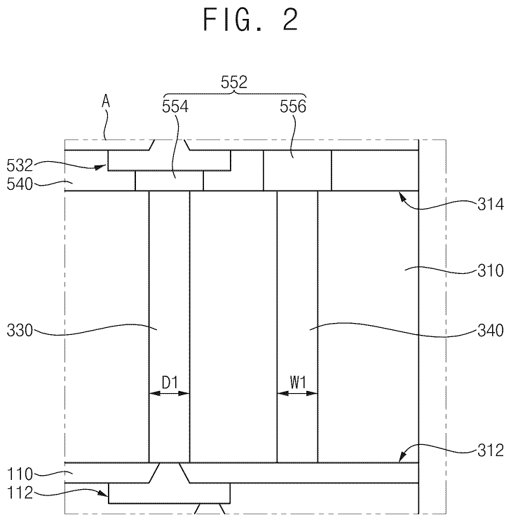

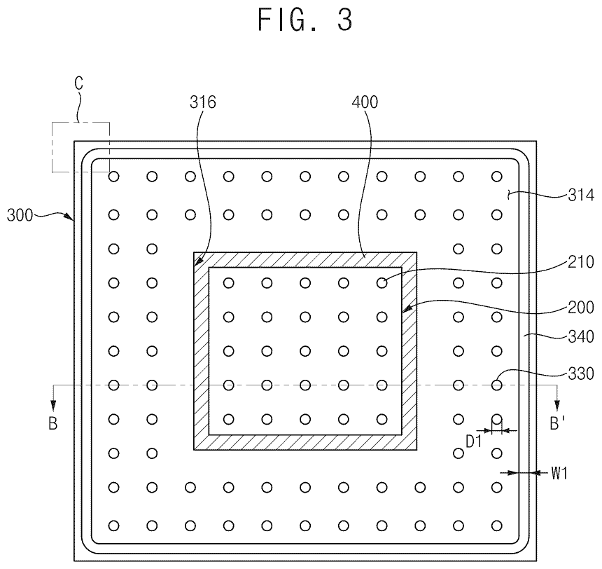

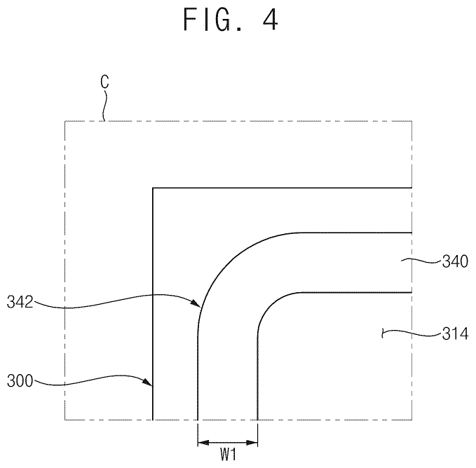

FIG. 1 is a cross-sectional view illustrating a semiconductor package in accordance with example embodiments. FIG. 2 is an enlarged cross-sectional view illustrating portion ‘A’ in FIG. 1. FIG. 3 is a plan view illustrating an upper surface of a core substrate of FIG. 1. FIG. 4 is an enlarged plan view illustrating portion ‘C’ in FIG. 3. FIG. 1 includes a cross section taken along the line B-B′ in FIG. 3.

Referring to FIGS. 1 to 4, a semiconductor package 10 may include a lower redistribution wiring layer 100, at least one semiconductor chip 200 disposed on the lower redistribution wiring layer 100, a core substrate 300 on the upper surface of the lower redistribution wiring layer 100 and surrounding the semiconductor chip 200, and an upper redistribution wiring layer 500 disposed on an upper surface 314 of the core substrate 300. Additionally, the semiconductor package 10 may further include external connection members 160 disposed on an outer surface of the lower redistribution wiring layer 100.

In example embodiments, the semiconductor package 10 may be a fan out package in which the lower redistribution wiring layer 100 extends to the core substrate 300 that covers, overlaps, or is on a side surface of the semiconductor chip 200. The lower redistribution wiring layer 100 and the upper redistribution wiring layer 500 may be formed through a wafer level or panel level redistribution wiring process. Additionally, the semiconductor package 10 may be provided as a unit package on which a second package is stacked.

Additionally, the semiconductor package 10 may be provided as a system in package (SIP). For example, one or more semiconductor chips may be disposed on the lower redistribution wiring layer 100. The semiconductor chips may include a logic chip including logic circuits and/or a memory chip. The logic chip may be a controller that controls memory chips. The memory chip may include various types of memory circuits, for example, DRAM, SRAM, flash, PRAM, ReRAM, FeRAM, MRAM, etc.

In example embodiments, the lower redistribution wiring layer 100 may have first redistribution wirings 102. The semiconductor chip 200 may be disposed on the lower redistribution wiring layer 100 and may be electrically connected to the first redistribution wirings 102. The lower redistribution wiring layer 100 may be provided on a front surface 202 of the semiconductor chip 200 and may function as a front redistribution wiring layer. Accordingly, the lower redistribution wiring layer 100 may be the front redistribution wiring layer (FRDL) of the fan out package.

In particular, the lower redistribution wiring layer 100 may include a plurality of first, second, third, and fourth lower insulating layers 110, 120, 130, and 140 and first redistribution wirings 102 provided in the first, second, third, and fourth lower insulating layers 110, 120, 130, and 140. The first redistribution wirings 102 may include first, second, and third lower redistribution wirings 112, 122, and 132.

The first, second, third, and fourth lower insulating layers 110, 120, 130, and 140 may include a polymer, a dielectric layer, etc. For example, the first, second, third, and fourth lower insulating layers 110, 120, 130, and 140 may include a photosensitive insulating layer such as a photo imageable dielectric (PID). The first, second, third, and fourth lower insulating layers 110, 120, 130, and 140 may be formed by a vapor deposition process, spin coating process, etc. The first redistribution wirings may include aluminum (Al), copper (Cu), tin (Sn), nickel (Ni), gold (Au), platinum (Pt), or an alloy thereof. The first redistribution wiring may be formed by a plating process, an electroless plating process, a vapor deposition process, etc.

In particular, the first lower insulating layer 110 may be provided on a lower surface 312 of the core substrate 300. The first lower redistribution wiring 112 may be formed on the first lower insulating layer 110. The first lower redistribution wirings 112 may be electrically connected to a plurality of through vias 330 of the core substrate 300 and chip pads 210 of the semiconductor chip 200 through first openings formed in the first lower insulating layer 110.

The second lower insulating layer 120 may be formed on the first lower insulating layer 110, and the second lower redistribution wiring 122 may be formed on the second lower insulating layer 120. The second lower redistribution wiring 122 may be electrically connected to the first lower redistribution wiring 112 through a second opening formed in the second lower insulating layer 120.

The third lower insulating layer 130 may be formed on the second lower insulating layer 120, and the third lower redistribution wiring 132 may be formed on the second lower insulating layer 120. The third lower redistribution wiring 132 may be electrically connected to the second lower redistribution wiring 122 through a third opening formed in the third lower insulating layer 120.

The fourth lower insulating layer 140 may be formed on the third lower insulating layer 130 and may expose portions of the third lower redistribution wirings 132. Lower bonding pads, such as Under Bump Metallurgy (UBM), may be disposed on the exposed portions of the third lower redistribution wirings 132. The lower bonding pad may be on the third lower redistribution wirings 132 and may be in contact with the external connection member 160. The fourth lower insulating layer 140 may function as a passivation layer.

It will be understood that the number and arrangement of the lower insulating layers 110, 120, 130, and 140 and the lower redistribution wirings 112, 122, and 132 of the lower redistribution wiring layer 100 are provided as examples, and the present inventive concept is not limited thereto.

In example embodiments, when viewed in plan view, the lower redistribution wiring layer 100 may include a first region as a chip mounting region that overlaps the semiconductor chip 200 mounted on the lower redistribution wiring layer 100 and a second region as a connector region surrounding the first region. The second region may be a fan-out region outside an area where the semiconductor chip is disposed.

In example embodiments, the semiconductor chip 200 may have a plurality of chip pads 210 on the front surface 202, that is, an active surface. The semiconductor chip 200 may be mounted on the lower redistribution wiring layer 100 such that the front surface on which the chip pads 210 are formed faces the lower redistribution wiring layer 100.

The semiconductor chip may be a logic chip including logic circuits. The logic chip may be a controller that controls memory chips. The first semiconductor chip may be a processor chip such as ASIC or an application processor AP as a host such as CPU, GPU, or SOC.

Although only a few chip pads are illustrated in the figures, it will be understood that the structures and arrangements of the chip pads are provided as examples, and the present inventive concept is not limited thereto. Additionally, although only one semiconductor chip is illustrated, the present inventive concept is not limited thereto, and a plurality of semiconductor chips may be stacked on the lower redistribution wiring layer 100.

In example embodiments, the core substrate 300 may be provided on the upper surface of the lower redistribution wiring layer 100 to surround the semiconductor chip 200 in plan view (i.e. the lower redistribution wiring layer 100 is on sidewalls of the semiconductor chip 200. The core substrate 300 may include a substrate 310 having a first surface (upper surface) 314 and a second surface (lower surface) 312 opposite to the first surface. The substrate 310 may include a glass substrate. The substrate 310 may have a cavity 316 in a middle region thereof. The cavity 316 may extend from the first surface 314 to the second surface 312 of the substrate 310.

The core substrate 300 has a plurality of through vias 330 that penetrate the substrate 310 and are electrically connected to the first redistribution wirings 102 and a shielding structure 340 that extends along an edge of the substrate 310 and penetrates the substrate 310.

The plurality of through vias 330 may extend in a vertical direction to penetrate the glass substrate 310. The plurality of through vias 330 may extend from the first surface 314 to the second surface 312 of the glass substrate 310. The through via 330 may function as a through glass electrode (Through Glass Via, TGV). The plurality of through vias 330 may be provided in the fan-out region outside the area where the semiconductor chip 200 is disposed, to electrically connect the lower redistribution wiring layer 100 and the upper redistribution wiring layer 500.

As illustrated in FIGS. 3 and 4, the shielding structure 340 may extend along the edge of the substrate 310. The shielding structure 340 may have a rectangular closed loop shape extending to surround the plurality of through vias 330. The shielding structure 340 may include four corner portions 342 of a rounded shape. The shielding structure 340 including a metal material may extend along the edge of the substrate 310 and may function as a heat spreader that dissipates heat from the semiconductor chip 200 in a horizontal direction to improve heat dissipation characteristics. Additionally, the shielding structure 340 including the round corner portions 342 may reduce the brittleness of the glass substrate 310 and reinforce its brittleness.

For example, each of the plurality of through vias 330 may have a first diameter D1. The shielding structure 340 may have a first width W1. The first width W1 may be the same as or different from the first diameter D1. The first width W1 may be within a range of 10 μm to 50 μm. The plurality of through vias 330 and the shielding structure 340 may include the same metal, such as copper (Cu). A thickness of the core substrate 300 may be within a range of 200 μm to 400 μm.

In example embodiments, a sealing member 400 may partially or fully fill a gap between the semiconductor chip 200 and an inner wall of the cavity 316 of the core substrate 300. The sealing member 400 may cover, overlap, or be on the side surface of the semiconductor chip 200. The sealing member 400 may expose a backside surface 204 of the semiconductor chip 200. In other words, the sealing member 400 may be on side surfaces of the semiconductor chip 200, but does not overlap a backside surface 204 of the semiconductor chip 200 in a cross-sectional view.

For example, the sealing member 400 may include an epoxy mold compound (EMC). The sealing member 400 may be formed by a molding process, screen printing process, lamination process, etc.

An upper surface of the sealing member 400 may be located on the same plane as the upper surface 314 of the core substrate 300. A lower surface of the sealing member 400 may be located on the same plane as the lower surface 312 of the core substrate 300.

In example embodiments, the upper redistribution wiring layer 500 may be disposed on the first surface 314 of the core substrate 300 and may include second redistribution wirings 502 each electrically connected to the plurality of through vias 330. The second redistribution wirings 502 may include of upper redistribution wirings 522 and 532 stacked in at least two layers. The second redistribution wirings 502 may be provided on the backside surface 204 of the semiconductor chip 200 and may serve as backside redistribution wirings. Accordingly, the upper redistribution wiring layer 500 may be a backside redistribution wiring layer (BRDL) of the fan out package.

The second redistribution wirings 502 may include a first upper redistribution wiring 522 and a second upper redistribution wiring 532 that are sequentially stacked. In this case, the second upper redistribution wiring 532 may correspond to a lowermost redistribution wiring among the second redistribution wirings, and the first upper redistribution wiring 522 may correspond to an uppermost redistribution wiring among the second redistribution wirings.

In particular, a first bonding pad 512 may be provided in a first upper insulating layer 510. The first bonding pad 512 may be a bump pad. The bump pad may include a solder pad or pillar pad. For example, the first bonding pad may include copper (Cu), aluminum (Al), tin (Sn), nickel (Ni), gold (Au), platinum (Pt), or an alloy thereof.

A second upper insulating layer 520 may be formed on the first upper insulating layer 510, and the first upper redistribution wiring 522 may be formed on the second upper insulating layer 520. The first upper redistribution wiring 522 may be electrically connected to the first bonding pad 512 through a first opening formed in the second upper insulating layer 520.

A third upper insulating layer 530 may be formed on the second upper insulating layer 520, and the second upper redistribution wiring 532 may be formed on the third upper insulating layer 530. The second upper redistribution wiring 532 may be electrically connected to the first upper redistribution wiring 522 through a second opening formed in the third upper insulating layer 530.

Second bonding pads 552 may be provided on the third upper insulating layer 530. The second bonding pads 552 may include a plurality of third pads 554 for bonding to the through vias and fourth pads 556 for bonding to the shielding structure. The plurality of third pads 554 may be respectively disposed on the second upper redistribution wirings 532 and mat be electrically connected to the second redistribution wirings 502. The fourth pad 556 may be disposed on the third upper insulating layer 530 and may be electrically insulated from the second redistribution wirings 502. In some embodiments, the fourth pad 556 may be disposed on a redistribution pad that is formed on the second upper insulating layer 520 together with the second upper redistribution wirings 532. In this case, the redistribution pad may be an electrically insulated dummy pad, and accordingly, the fourth pad 556 disposed on the dummy pad may be electrically insulated from the second redistribution wirings 502.

A fourth upper insulating layer 540 may be provided on the third upper insulating layer 530 to expose the second bonding pads 552. The fourth upper insulating layer 540 may include silicon oxide, silicon nitride, silicon carbonitride, etc. The fourth upper insulating layer 540 may serve as a passivation layer.

As illustrated in FIG. 2, the upper redistribution wiring layer 500 may be bonded to the core substrate 300 by hybrid bonding. The fourth upper insulating layer 540 of the upper redistribution wiring layer 500 may be directly bonded to the upper surface 314 of the glass substrate 310 of the core substrate 300, end portions of the plurality of through vias 330 exposed from the upper surface 314 of the glass substrate 310 may be bonded to the third pads 554 of the upper redistribution wiring layer 500 by copper-copper hybrid bonding (Cu—Cu hybrid bonding), and an end portion of the shielding structure 340 exposed from the upper surface 314 of the glass substrate 310 may be bonded to the fourth pad 556 of the upper redistribution wiring layer 500 by copper-copper hybrid bonding (Cu—Cu Hybrid Bonding).

Accordingly, the plurality of through vias 330 may be electrically connected to the second redistribution wirings 502 through the third pads 554. The shielding structure 340 bonded to the fourth pad 556 may be electrically insulated.

For example, the first, second, and third upper insulating layers 510, 520, and 530 may include polymer, dielectric layer, etc. The first, second, and third upper insulating layers 510, 520, and 530 may include a photosensitive insulating material (PID) or an insulating film such as Ajinomoto Build-Up Film (ABF). The second redistribution wirings may include copper (Cu), aluminum (Al), tin (Sn), nickel (Ni), gold (Au), platinum (Pt), or an alloy thereof.

It will be understood that the number and arrangement of the upper insulating layers and the upper redistribution wirings of the upper redistribution wiring layer are provided as examples, and the present inventive concept is not limited thereto.

In example embodiments, the external connection members 160 may be disposed on the lower bonding pads on the outer surface of the lower redistribution wiring layer 100. For example, the external connection member 160 may include a solder ball. The solder ball may have a diameter of 300 μm to 500 μm. The semiconductor package 10 may be mounted on a module substrate (not illustrated) using the solder balls to form a memory module.

As mentioned above, the semiconductor package 10 as a fan out package may include the lower redistribution wiring layer 100, the semiconductor chip 200 disposed on the lower redistribution wiring layer 100, the core substrate 300 surrounding the semiconductor chip 200 on the upper surface of the lower redistribution wiring layer 100, and the upper redistribution wiring layer 500 disposed on the upper surface 314 of the core substrate 300.

The core substrate 300 may include the plurality of through vias 330 that penetrate the glass substrate 310 and are electrically connected to the first redistribution wirings 102, and the shielding structure 340 that penetrates the glass substrate 310 and extends along an edge of the substrate 310. The shielding structure 340 including a metal material may extend along the edge of the glass substrate 310 and may function as a heat spreader that dissipates heat from the semiconductor chip 200 in a horizontal direction, to thereby improve heat dissipation characteristics. Further, the shielding structure 340 including round corner portions 342 may reduce the brittleness of the glass substrate 310 and reinforce the structure to reduce brittleness.

In addition, the core substrate 300 may be bonded to the upper redistribution wiring layer 500 by hybrid bonding and then the lower redistribution wiring layer 100 may be formed on the core substrate 300 to form the semiconductor package 10. Accordingly, a manufacturing process may be simplified and the number of processes that involve turning over intermediate structures during the manufacturing process may be reduced to decrease the turn-around time (TAT).

Hereinafter, a method of manufacturing the semiconductor package of FIG. 1 will be described.

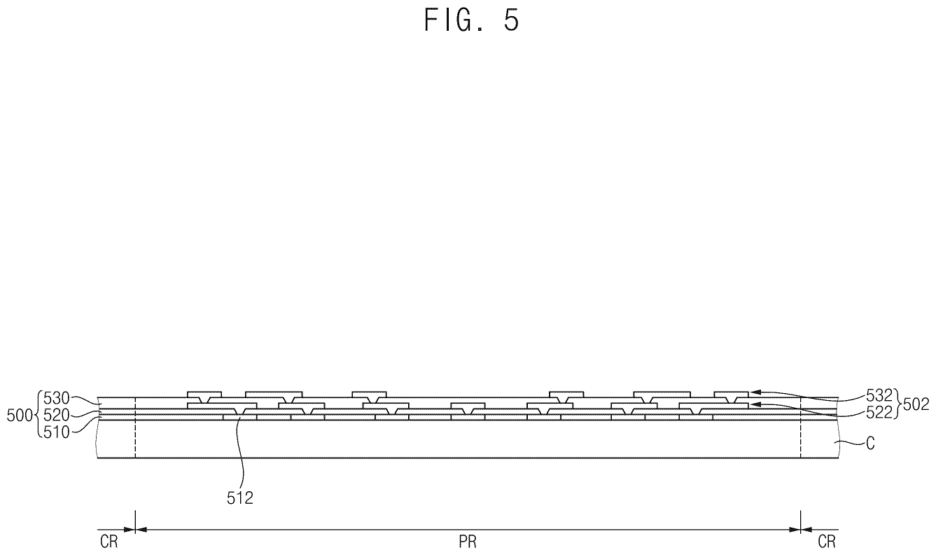

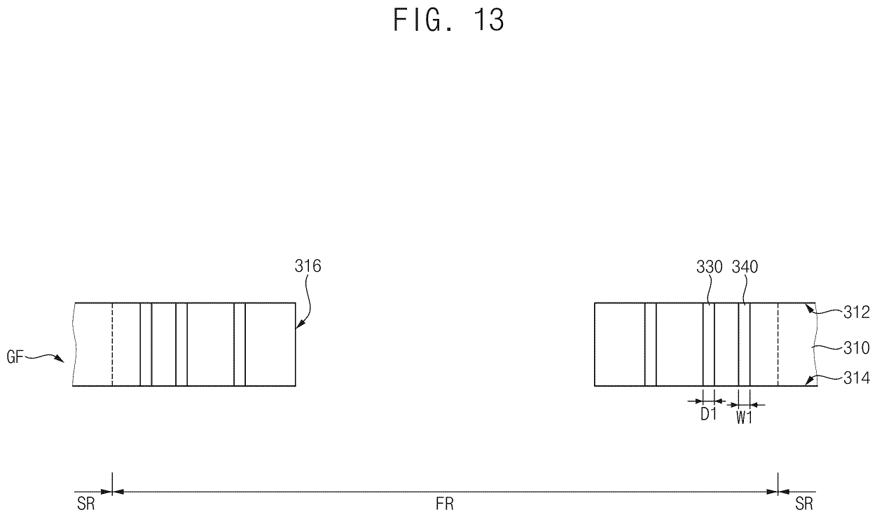

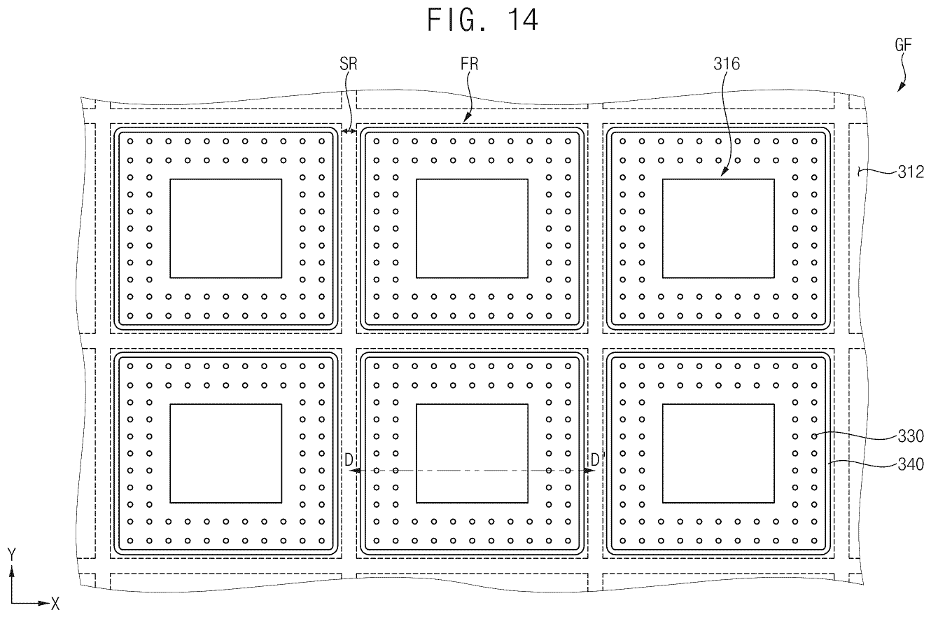

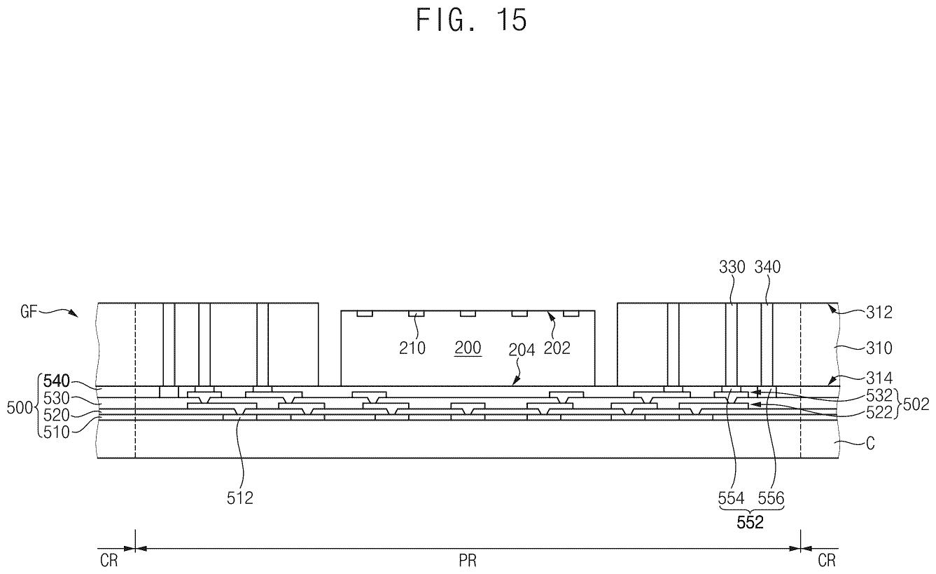

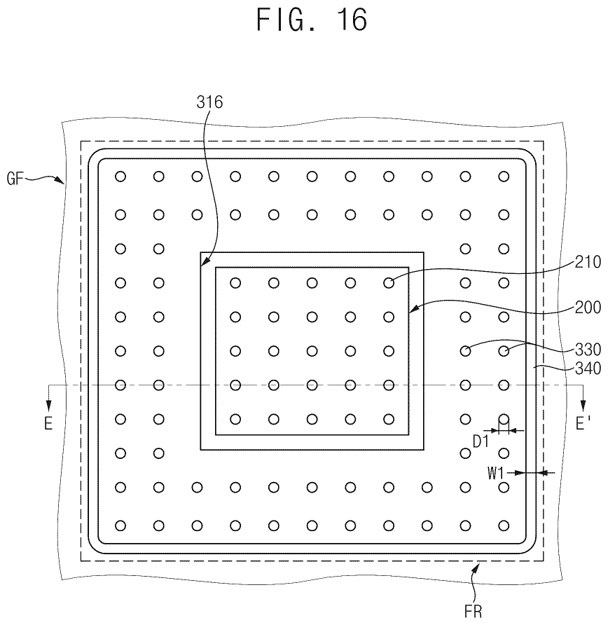

FIGS. 5 to 21 are views illustrating a method of manufacturing a semiconductor package in accordance with example embodiments. FIGS. 5 to 13, 15, and 17 to 21 are cross-sectional views illustrating a method of manufacturing a semiconductor package in accordance with example embodiments. FIG. 14 is a plan view illustrating a core substrate including a glass substrate portion of FIG. 13. FIG. 16 is a plan view of FIG. 15. FIG. 13 is a cross-sectional view taken along the line D-D′ in FIG. 14.

Referring to FIGS. 5 to 7, an upper redistribution wiring layer 500 having second redistribution wirings 502 may be formed on a carrier substrate C.

In example embodiments, the carrier substrate C may include a wafer substrate as a base substrate on which a plurality of semiconductor chips is disposed on the upper redistribution wiring layer and a core substrate is formed to accommodate them. The carrier substrate C may have a shape corresponding to the wafer or panel on which a semiconductor process is performed. For example, the carrier substrate C may include a silicon substrate, a glass substrate, a non-metallic or metallic plate, etc.

The carrier substrate C may include a package region PR on which the semiconductor chip is mounted and a cutting region CR surrounding the package region PR. As will be described later, the upper redistribution wiring layer 500 and the core substrate formed on the carrier substrate C may be cut along the cut region CR that divides the plurality of package regions PR to be individualized.

As illustrated in FIG. 5, in example embodiments, a first upper insulating layer 510 having first bonding pads 512 may be formed on the carrier substrate C. Although not illustrated in the figures, after forming a release layer, a barrier metal layer, a seed layer, and the first upper insulating layer on the carrier substrate C, the first upper insulating layer may be patterned to form openings that expose first bonding pad regions. Then, a plating process may be performed on the seed layer to form the first bonding pads 512 within the openings.

For example, the first upper insulating layer 510 may include a polymer, a dielectric layer, etc. The first upper insulating layer 510 may include an insulating layer such as a photosensitive insulating material (PID) or Ajinomoto Build-Up Film (ABF). The first upper insulating layer may be formed by a spin coating process, a vapor deposition process, etc.

The first bonding pad 512 may be a bump pad. The bump pad may include a solder pad or pillar pad. For example, the first bonding pad may include copper (Cu), aluminum (Al), tin (Sn), nickel (Ni), gold (Au), platinum (Pt), or an alloy thereof.

Then, a second upper insulating layer 520 may be formed on the first upper insulating layer 510 to cover the first bonding pads 512, and then the second upper insulating film 520 may be patterned to form first openings that expose at least portions of the first bonding pads 512 respectively.

For example, the second upper insulating layer 520 may include a polymer, a dielectric layer, etc. The second upper insulating layer 520 may include an insulating film such as a photosensitive insulating material (PID) or Ajinomoto Build-Up Film (ABF). The second upper insulating layer may be formed by a spin coating process, a vapor deposition process, etc.

Then, first upper redistribution wirings 522 may be formed on the second upper insulating layer 520 to be electrically connected to the first bonding pads 512 through the first openings.

For example, the first upper redistribution wirings 522 may be formed by forming a seed layer on a portion of the second upper insulating layer 520 and in the first opening, patterning the seed layer, and performing an electrolytic plating process. Accordingly, at least a portion of the first upper redistribution wiring 522 may directly contact the first bonding pad 512 through the first opening. For example, the first upper redistribution wiring may include copper (Cu), aluminum (Al), tin (Sn), nickel (Ni), gold (Au), platinum (Pt), or an alloy thereof.

Similarly, a third upper insulating layer 530 may be formed on the second upper insulating layer 520 to cover or overlap the first upper redistribution wirings 522, and the third upper insulating layer 530 may be patterned to form openings that expose at least portions of the first upper redistribution wirings 522 respectively. Then, second upper redistribution wirings 532 may be formed on the third upper insulating layer 530 to directly contact the first upper redistribution wirings 522 through the second openings.

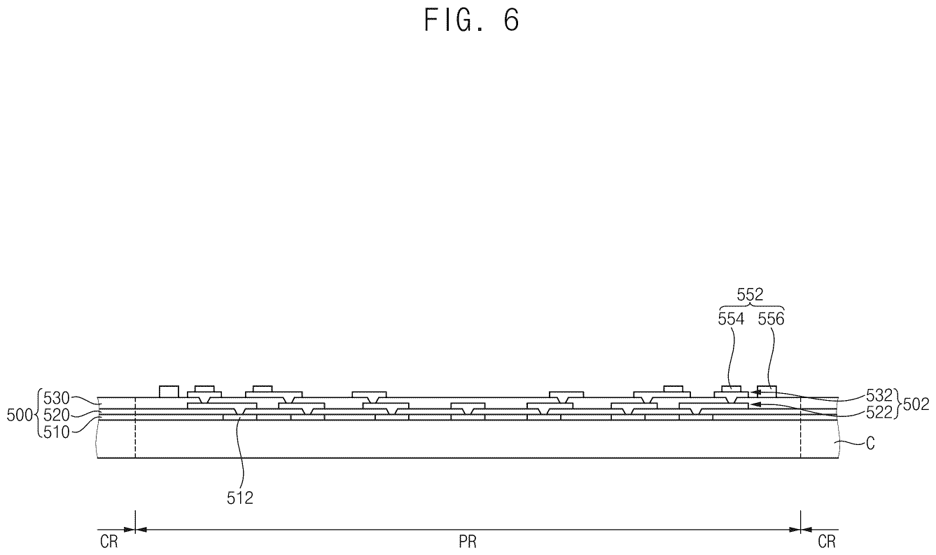

As illustrated in FIG. 6, second bonding pads 552 may be formed on the third upper insulating layer 530. The second bonding pads 552 may include third pads 554 for bonding to through vias and a fourth pad 556 for bonding to a shielding structure.

In particular, a seed layer may be formed on the third upper insulating layer 530, and a photoresist pattern having openings that expose second bonding pad regions may be formed on the seed layer. The openings may include first openings that expose third pad regions and a second opening that exposes a fourth pad region. The first openings may have a circular or polygonal cross-sectional shape corresponding to shapes of the through vias. The second opening may have a rectangular closed loop cross-sectional shape corresponding to a shape of the shielding structure.

Then, a plating process may be performed to form the second bonding pads 552 within the openings of the photoresist pattern. The second bonding pads may include a metal material. The second bonding pads may include the same material as the second upper redistribution wirings 532. The second bonding pads may include copper (Cu). The second bonding pads 552 may include a plurality of third pads 554 formed in the first openings and the fourth pad 556 formed in the second opening. Then, after removing the photoresist pattern, portions of the seed layer exposed by the upper bonding pads may be removed.

A plurality of third pads 554 may be respectively disposed on the second upper redistribution wirings 532 and may be electrically connected to the second redistribution wirings 502. The fourth pad 556 may be disposed on the third upper insulating layer 530 and may be electrically insulated from the second redistribution wirings 502.

In some embodiments, the fourth pad may be formed on a redistribution pad that is formed on the second upper insulating layer 520 together with the second upper redistribution wirings 532. In this case, the second opening of the photoresist pattern may expose a portion of the seed layer formed on the redistribution pad on the third upper insulating layer 530, that is, the fourth pad region, and a plating process may be performed to form the fourth pad on a portion of the seed layer on the redistribution pad. At this time, the redistribution pad may be an electrically insulated dummy pad, and accordingly, the fourth pad formed on the dummy pad may be electrically insulated from the second redistribution wirings 502.

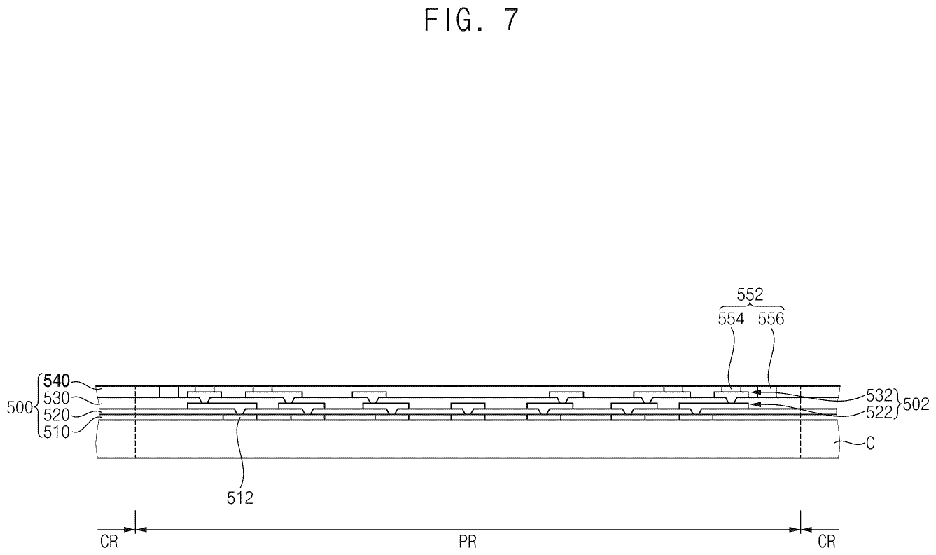

As illustrated in FIG. 7, a fourth upper insulating layer 540 may be formed on the third upper insulating layer 530 to expose the second bonding pads 552. The fourth upper insulating layer 540 may include silicon oxide, silicon nitride, silicon carbonitride, etc. The fourth upper insulating layer 540 may serve as a passivation layer.

In some embodiments, after forming the fourth upper insulating layer 540 on the third upper insulating layer 530, the fourth upper insulating layer 540 may be patterned to form openings that expose second bonding pad regions, and the second bonding pads 552 may be formed within the openings.

Thus, the upper redistribution wiring layer 500 having the first, second third, and fourth upper insulating layers 510, 520, 530, and 540 may be formed. The upper redistribution wiring layer 500 may be a backside redistribution wiring layer (BRDL) of a fan out package. The upper redistribution wiring layer 500 may include the second redistribution wirings 522 and 532 stacked in at least two layers. The second redistribution wirings 502 may include the first and second upper redistribution wirings 522 and 532 that are vertically stacked. The first bonding pads 512 may be exposed from a first surface of the upper redistribution wiring layer 500. The second bonding pads 552 may be exposed from a second surface of the upper redistribution wiring layer 500 that is opposite to the first surface.

When viewed in plan view, the upper redistribution wiring layer 500 may include a first region as a chip mounting region that overlaps a semiconductor chip to be mounted on the upper redistribution wiring layer 500 and a second region as a connector region surrounding the first region, as will be described later. The second region may be a fan-out region outside an area where the semiconductor chip is disposed.

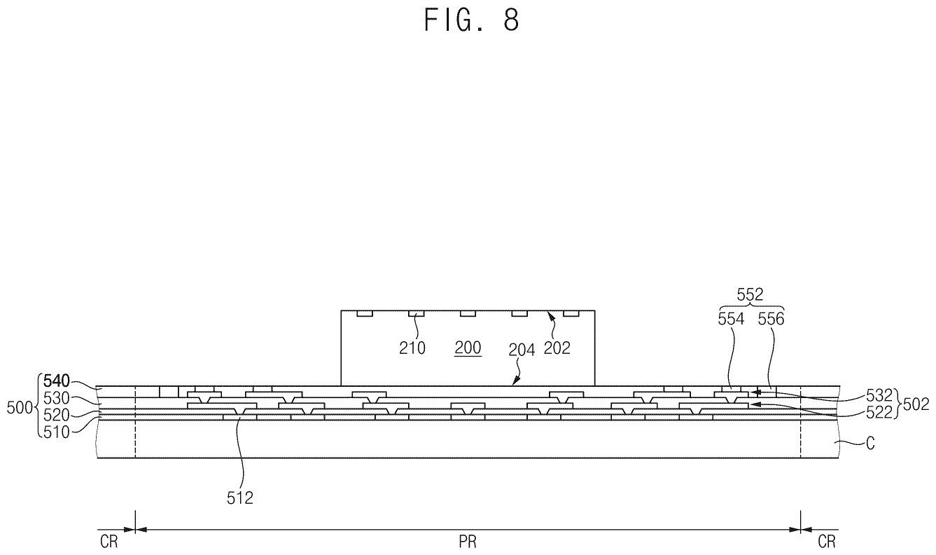

Referring to FIG. 8, at least one semiconductor chip 200 may be mounted on an upper surface of the upper redistribution wiring layer 500.

In example embodiments, the semiconductor chip 200 may be disposed in the first region, which is a fan-in region of the upper redistribution wiring layer 500. The semiconductor chip 200 may be mounted on the second surface of the upper redistribution wiring layer 500 by an adhesive film or a thermal interface material layer. The semiconductor chip 200 may be disposed such that a backside surface 204 opposite to a front surface 202 on which chip pads 210 are formed, that is, an active surface, faces the upper redistribution wiring layer 500. In some embodiments, one semiconductor chip may be disposed in the first region, but the present inventive concept may not be limited thereto, and a plurality of semiconductor chips may be disposed in the first region.

The semiconductor chip may be a logic chip including logic circuits. The logic chip may be a controller that controls memory chips. The semiconductor chip may be a processor chip or an application processor AP such as an ASIC as a host such as CPU, GPU, or SOC.

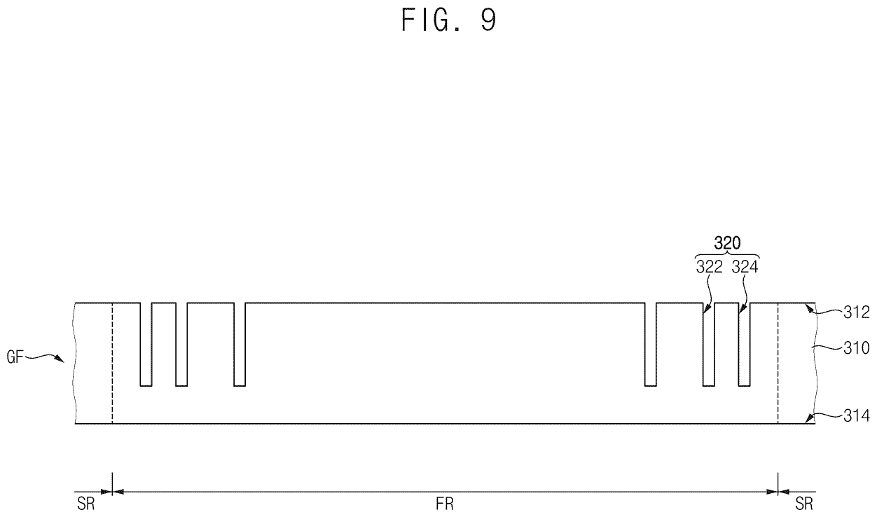

Referring to FIGS. 9 to 14, a glass frame GF in which a plurality of core substrates are formed may be formed.

In example embodiments, the glass frame GF may include a glass substrate 310 having a first surface 312 and a second surface 314 opposite to the first surface 312. The glass frame GF may include a frame region FR for the core substrate and a scribe lane region SR surrounding the frame region FR. The frame region FR may correspond to the package region PR of the carrier substrate C, and the scribe lane region SR may correspond to the cutting region CR of the carrier substrate C. As will be described later, the glass frame GF may be cut along the cutting region CR to be individualized into one core substrate. The core substrate may be used as an electrical connection support frame for forming a semiconductor package with a fan-out package structure.

As illustrated in FIG. 9, recesses 320 having predetermined depths may be formed in the first surface 312 of a glass substrate 310. The recesses 320 may be formed by a laser drilling process. In some embodiments, the recesses 320 may be formed by forming preliminary recesses through a laser drilling process and expanding diameters of the preliminary recesses through an etching process. For example, a laser source used in the laser drilling process may include a solid-state ultraviolet laser (such as a Nd: YAG laser) that emits a pulsed laser beam with a wavelength of 355 nm.

The recesses 320 may include opening holes 322 for forming a plurality of through vias and a trench 324 for forming a shielding structure. The depths of the recesses 320 from the first surface 312 may be in a range of 200 μm to 400 μm.

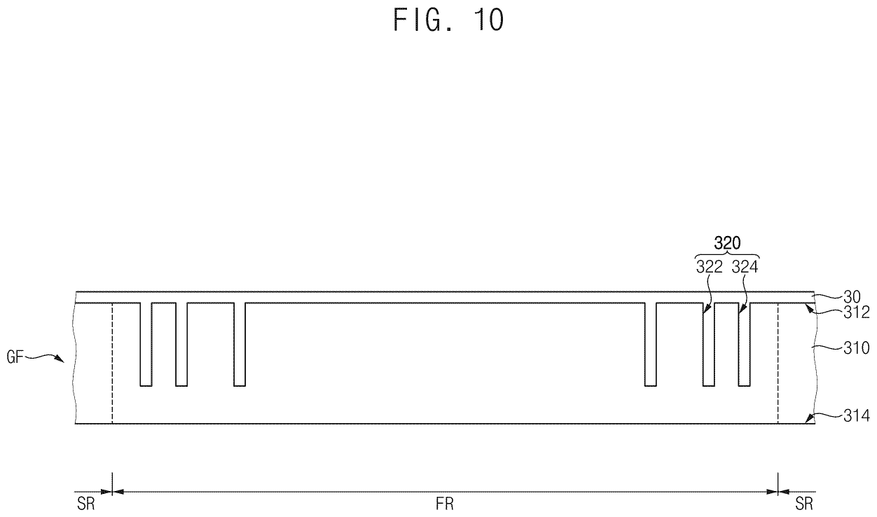

As illustrated in FIG. 10, a seed layer may be formed on the first surface 312 of the glass substrate 310 and on inner surfaces of the recesses, and a plating process may be performed on the seed layer to form an electrode layer 30 to fill the recesses 320. The electrode layer 30 may include a metal material such as copper (Cu).

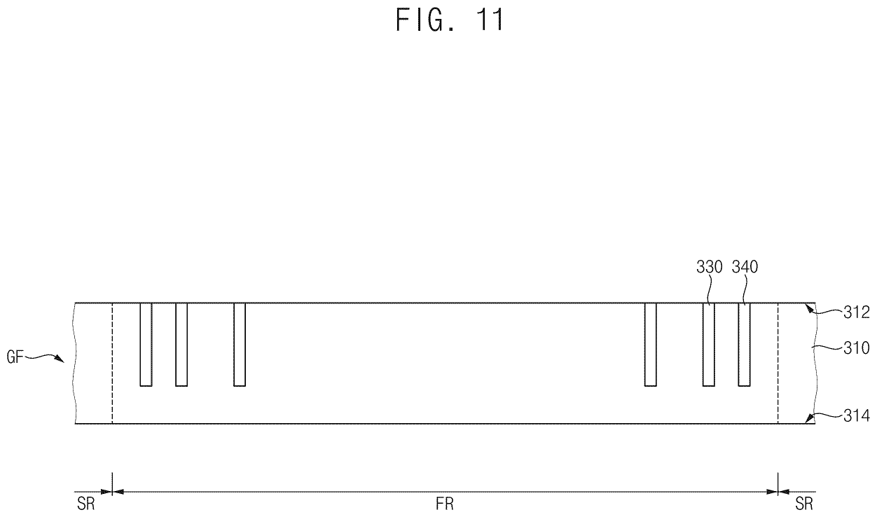

As illustrated in FIG. 11, an upper portion of the electrode layer 30 may be removed until the first surface 312 of the glass substrate 310 is exposed, to form a plurality of through vias 330 in the opening holes 322 and a shielding structure 340 in the trench 324.

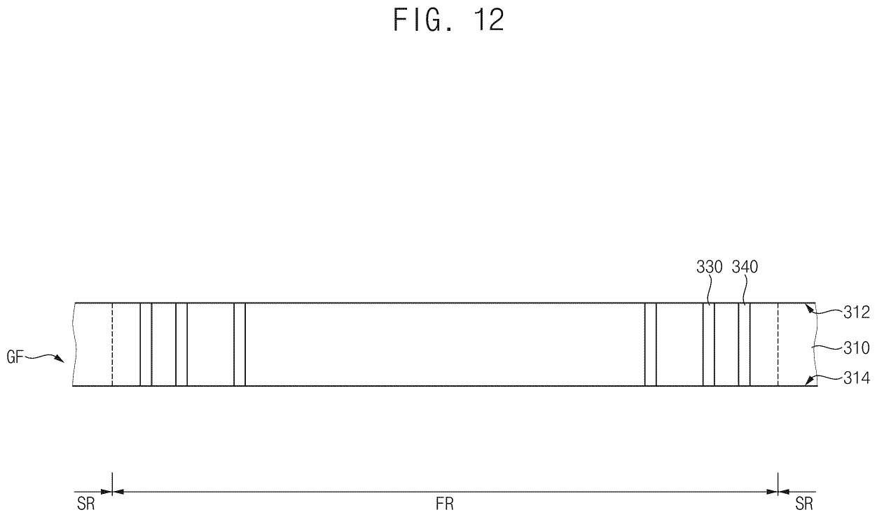

As illustrated in FIG. 12, the second surface 314 of the glass substrate 310 may be partially removed to expose lower surfaces of the plurality of through vias 330 and the shielding structure 340. Accordingly, the plurality of through vias 330 and the shielding structure 340 may penetrate the glass substrate 310. The plurality of through vias 330 may extend through the glass substrate 310 in the fan-out region. The through via 330 may function as a through glass electrode (Through Glass Via, TGV).

As illustrated in FIGS. 13 and 14, a middle portion of the glass substrate 310a may be removed to form a cavity 316 for accommodating the semiconductor chip 200. The cavity 316 may extend from the first surface 312 to the second surface 314 of the glass substrate 310. The cavity 316 may be positioned to correspond to the first region where the semiconductor chip 200 is disposed.

Each of the plurality of through vias 330 may have a first diameter D1. The shielding structure 340 may have a first width W1. The first width W1 may be the same as or different from the first diameter D1. The first width W1 may be within a range of 10 μm to 50 μm. The shielding structure 340 may have a spacing distance of several to tens of micrometers from the scribe lane region SR.

The shielding structure 340 may extend along an edge of the frame region FR. The shielding structure 340 may have a rectangular closed loop shape extending to surround the plurality of through vias 330.

In some embodiments, first and second insulating layers may be provided on the first surface 312 and the second surface 314 of the glass substrate 310, respectively. The first and second insulating layers may expose both end portions of the plurality of through vias 330 and both end portions of the shielding structure 340. The first and second insulating layers may include silicon oxide, silicon nitride, silicon carbonitride, etc.

Referring to FIGS. 15 and 16, the glass frame GF may be placed on the upper surface of the upper redistribution wiring layer 500. The semiconductor chip 200 may be placed within the cavity 316 of the glass frame GF.

In example embodiments, the glass frame GF may be bonded to the upper redistribution wiring layer 500 through hybrid bonding. The fourth upper insulating layer 540 of the upper redistribution wiring layer 500 may be directly bonded to the second surface 314 of the glass substrate 310 of the glass frame GF, and the exposed end portions of the plurality of through vias 330 may be bonded to the third pads 554 of the upper redistribution wiring layer 500 by Cu—Cu Hybrid Bonding, and the exposed end portions of the shielding structure 340 may be bonded to the fourth pad 556 of the upper redistribution wiring layer 500 by Cu—Cu Hybrid Bonding. Accordingly, the plurality of through vias 330 may be electrically connected to the second redistribution wirings 502 through the third pads 554. The shielding structure 340 bonded to the fourth pad 556 may be electrically insulated.

The semiconductor chip 200 may be spaced apart from an inner wall of the cavity 316. Accordingly, a gap may be formed between a side surface of the semiconductor chip 200 and the inner wall of the cavity 316. The front surface 202 of the semiconductor chip 200 on which the chip pads 210 are formed may be exposed from the first surface 312 of the glass substrate 310. The front surface 202 of the semiconductor chip 200 may be located lower than the first surface 312 of the glass frame GF. A thickness of the semiconductor chip 200 may be smaller than a thickness of the glass frame GF.

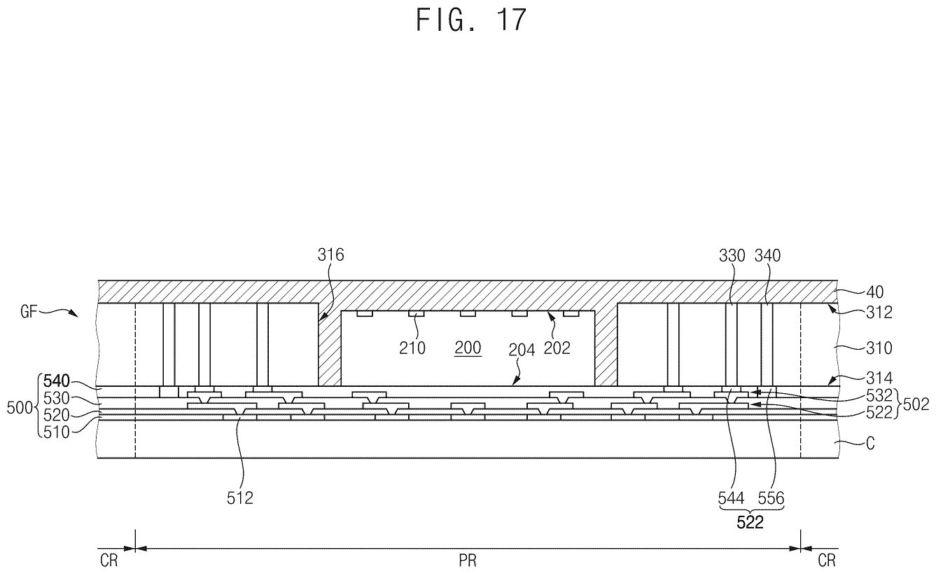

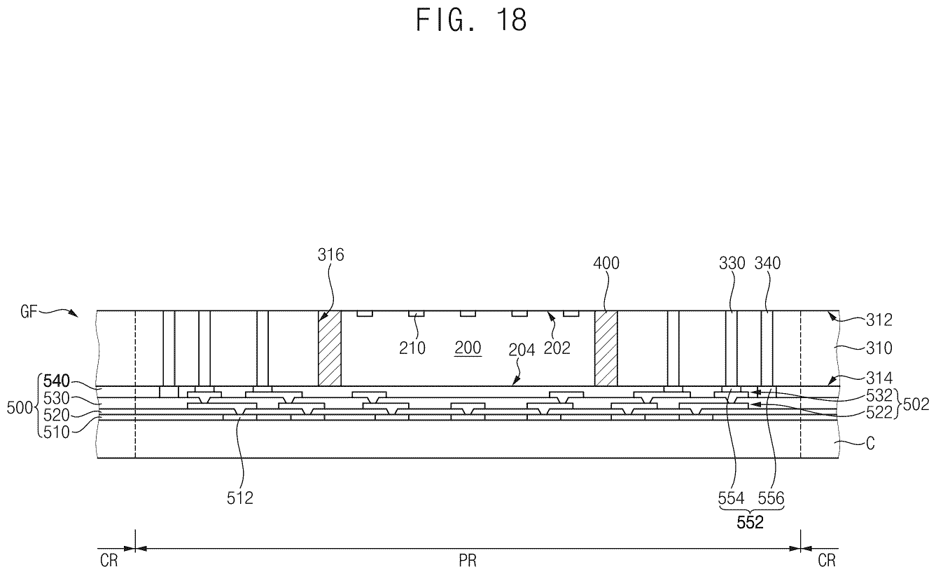

Referring to FIGS. 17 and 18, a sealing material 40 may be formed on the first surface 312 of the glass frame GF to cover the semiconductor chip 200, and an upper portion of the sealing material 40 may be removed to form a sealing member 400 that exposes the first surface 312 of the glass frame GF.

The sealing material 40 may be formed to fill the gap between the side surface of the semiconductor chip 200 and the inner wall of the cavity 316. For example, the sealing material 40 may include an insulating material such as epoxy resin (thermosetting dielectric material), a photosensitive insulating material (PID), an insulating film such as ABF, etc. When the sealing material 40 includes an insulating film such as ABF, the sealing material 40 may be formed by a lamination process.

When removing the upper portion of the sealing material 40, the first surface 312 of the glass frame GF may also be removed to expose the front surface 202 of the semiconductor chip 200. Accordingly, the sealing member 400 may expose the first surface 312 of the glass frame GF and the front surface 202 of the semiconductor chip 200. An upper surface of the sealing member 400, the first surface 312 of the glass frame GF and the front surface 202 of the semiconductor chip 200 may be located on the same plane. The sealing member 400 may fill the gap between the inner wall of the cavity 316 and the semiconductor chip 200.

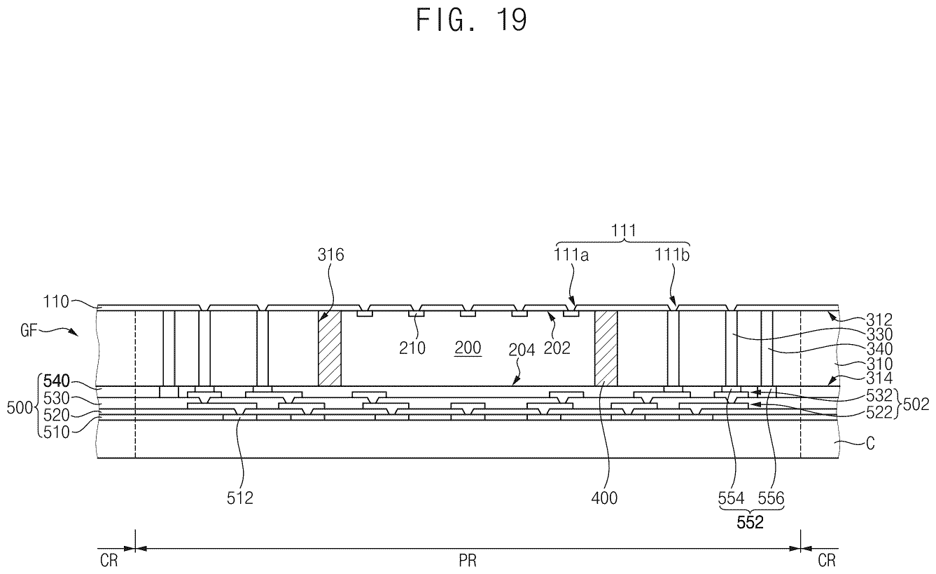

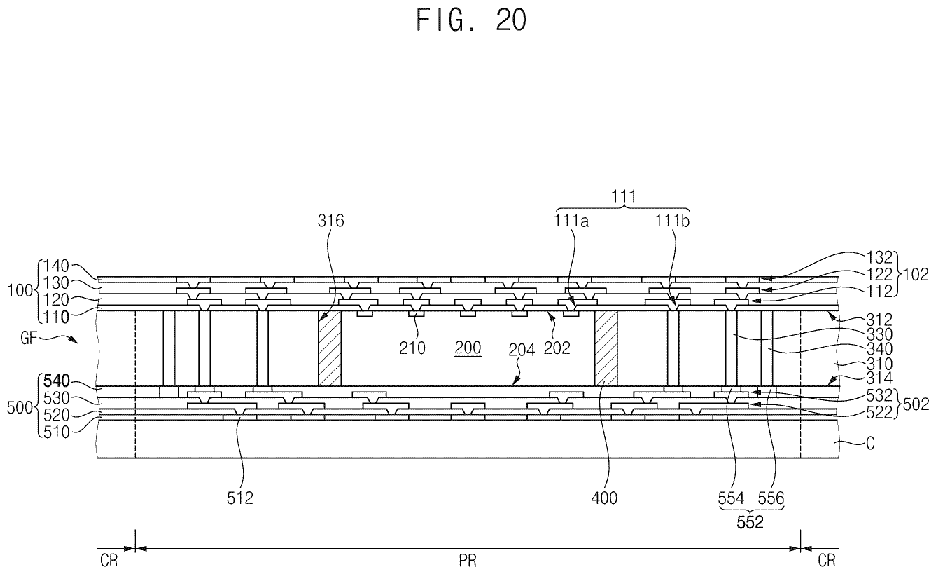

Referring to FIGS. 19 and 20, a lower redistribution wiring layer 100 having first redistribution wirings 102 may be formed on the first surface 312 of the glass substrate GF. The first redistribution wirings 102 may be electrically connected to the plurality of through vias 330 and the chip pads 210 of the semiconductor chip 200.

As illustrated in FIG. 19, after a first lower insulating layer 110 is formed on the first surface 312 of the glass substrate GF, the first lower insulating layer 110 may be patterned to form openings 111. The openings 111 may include first openings 111a that expose the chip pads 210 of the semiconductor chip 200 and second openings 111b that expose one of the end portions of the plurality of through vias 330. The first lower insulating layer 110 may include a polymer, a dielectric layer, etc. The first lower insulating layer 110 may be formed by a vapor deposition process, spin coating process, etc.

As illustrated in FIG. 20, after a seed layer is formed on the exposed chip pads 210 and the plurality of through vias 330 and in the openings, the seed layer may be patterned and an electrolytic plating process may be performed to form first lower redistribution wirings 112. Accordingly, at least portions of the first lower redistribution wirings 112 may be electrically connected to the chip pads 210 and the plurality of through vias 330 through the openings. The first lower redistribution wiring may include aluminum (Al), copper (Cu), tin (Sn), nickel (Ni), gold (Au), platinum (Pt), or an alloy thereof.

Then, after forming a second lower insulating layer 120 on the first lower insulating layer 110, the second lower insulating layer 120 may be patterned to form openings that expose the first lower redistribution wirings 112, respectively. Then, second lower redistribution wirings 122 may be formed on the second lower insulating layer 120 to be electrically connected to the first lower redistribution wirings 112 through the openings.

Then, after forming a third lower insulating layer 130 on the second lower insulating layer 120, the third lower insulating layer 130 may be patterned to form openings that expose the second lower redistribution wirings 122, respectively. Then, third lower redistribution wirings 132 may be formed on the third lower insulating layer 130 to be electrically connected to the second lower redistribution wirings 122 through the openings. Then, a fourth lower insulating layer 140 may be formed on the third lower insulating layer 130 to cover the third lower redistribution wirings 132.

The fourth lower insulating layer 140 may function as a passivation layer. Then, the fourth lower insulating layer 140 may be partially removed through a via forming process to expose portions of the third lower redistribution wirings 132. A lower bonding pad (not illustrated) such as UBM may be formed on the third lower redistribution wiring 132 exposed by the fourth lower insulating layer 140 by a plating process.

The fourth lower insulating layer may include an insulating layer such as a photosensitive insulating material (PID) or ABF. The fourth lower insulating layer 140 may include the same or different material from the first, second, and third lower insulating layers 110, 120, and 130.

Accordingly, the lower redistribution wiring layer 100 having the first redistribution wirings 102 as a front redistribution wiring layer (FRDL) may be formed on the glass frame GF. The lower redistribution wiring layer 100 may include the stacked first, second, third, and fourth lower insulating layers 110, 120, 130, and 140 and the first redistribution wirings in the first, second third, and fourth lower insulating layers 110, 120, 130, and 140. The first redistribution wirings 102 may include the first, second, and third lower redistribution wirings 112, 122, and 132.

It will be understood that the number, size, and arrangement of the lower insulating layers 110, 120, 130, and 140 and the lower redistribution wirings 112, 122, and 132 of the lower redistribution wiring layer 100 are provided as examples, and the present inventive concept is not limited thereto.

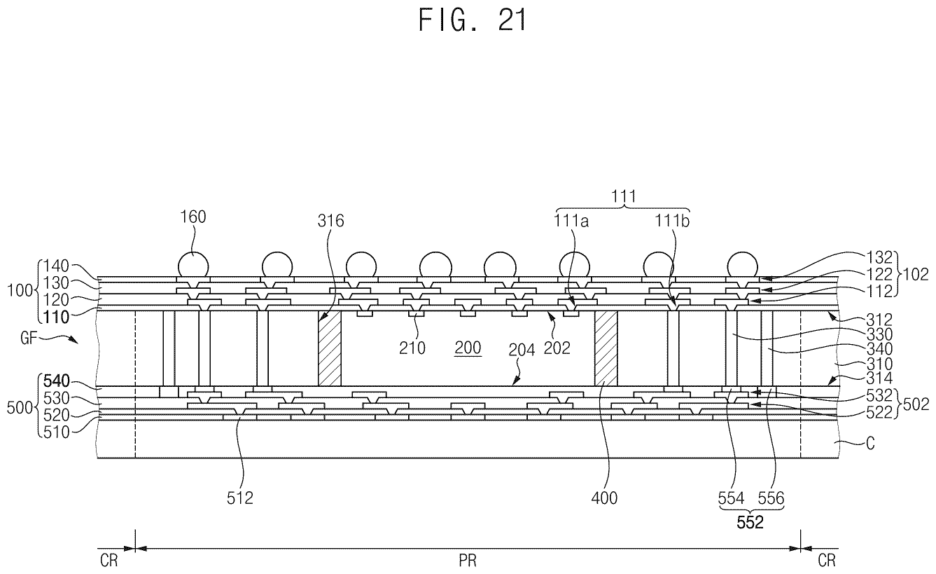

Referring to FIG. 21, external connection members 160 may be formed on an outer surface of the lower redistribution wiring layer 100 to be electrically connected to the first redistribution wirings 102.

In example embodiments, a solder ball may be formed as the external connection member on the lower bonding pad on a portion of the third lower redistribution wiring 132. The solder ball may have a diameter of 300 μm to 500 μm.

Then, the carrier substrate C may be removed and the glass frame GF may be separated into individual core substrates through a sawing process to form the fan-out package of semiconductor package 10 of FIG. 1 including the core substrate accommodating the semiconductor chip 200, the lower redistribution wiring layer 100 on the first surface of the core substrate, and the upper redistribution wiring layer 500 on the second surface of the core substrate.

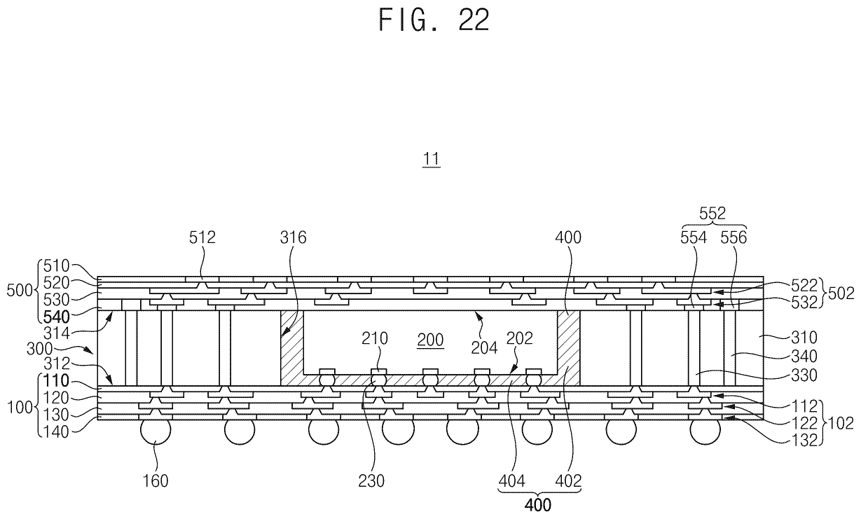

FIG. 22 is a cross-sectional view illustrating a semiconductor package in accordance with example embodiments. The semiconductor package is substantially the same as the semiconductor package described with reference to FIGS. 1 to 4 except for a connection relationship between a semiconductor chip and a lower redistribution wiring layer 100. Thus, same reference numerals may be used to refer to the same or like elements and any further repetitive explanation concerning the above elements will be omitted.

Referring to FIG. 22, a semiconductor package 11 may include a lower redistribution wiring layer 100, at least one semiconductor chip 200 disposed on the lower redistribution wiring layer 100, a core substrate 300 surrounding in plan view the at least one semiconductor chip 200 on the lower redistribution wiring layer 100, and an upper redistribution wiring layer 500 disposed on an upper surface 314 of the core substrate 300.

In example embodiments, the semiconductor chip 200 may have a plurality of chip pads 210 on a front surface 202, that is, an active surface. The semiconductor chip 200 may be disposed within a cavity 316 of the core substrate 300 such that the front surface 202 on which the chip pads 210 are formed faces the lower redistribution wiring layer 100.

The semiconductor chip 200 may be mounted on the lower redistribution wiring layer 100 via conductive bumps 230. The conductive bump 230 may be disposed between a first lower redistribution wiring 112 of the lower redistribution wiring layer 100 and the chip pad 210 of the semiconductor chip 200 in order to electrically connect the semiconductor chip 200 and the first redistribution wiring 102.

A sealing member 400 may partially or fully fill a gap between in inner wall of the cavity 316 and the semiconductor chip 200. The sealing member 400 may include a first sealing portion 402 that covers or overlaps the upper surface of the lower redistribution wiring layer 100 around the semiconductor chip 200 and a second sealing portion 404 that covers or overlaps the front surface 202 of the semiconductor chip 200. The second sealing portion 404 of the sealing member 400 may fill gaps between the conductive bumps 230 on the front surface 202 of the semiconductor chip 200.

Accordingly, the first lower redistribution wirings 112 of the lower redistribution wiring layer 100 may be electrically connected to a plurality of through vias 330 and the conductive bumps 230 of the core substrate 300.

Hereinafter, a method of manufacturing the semiconductor package of FIG. 22 will be described.

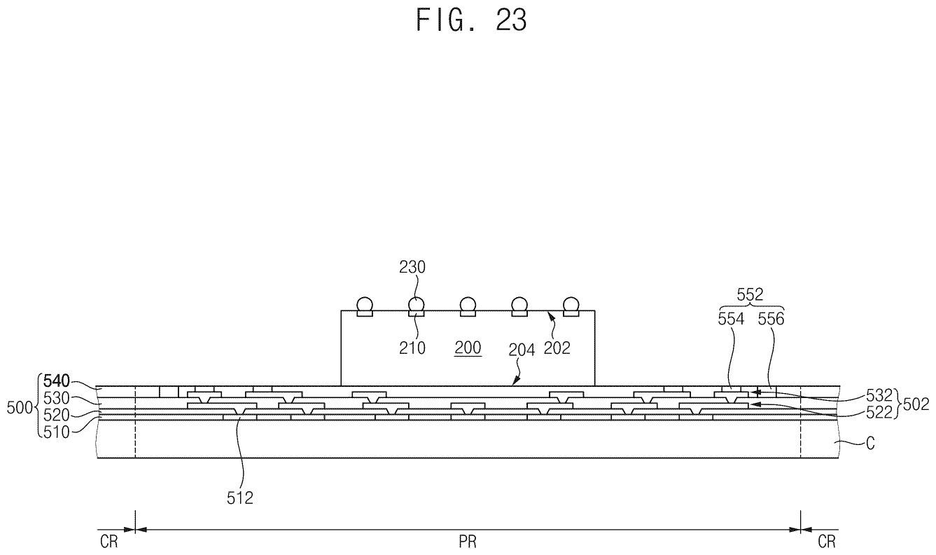

FIGS. 23 to 27 are cross-sectional views illustrating a method of manufacturing a semiconductor package in accordance with example embodiments.

Referring to FIG. 23, processes the same as or similar to the processes described with reference to FIGS. 5 to 8 may be performed to dispose a semiconductor chip 200 on an upper redistribution wiring layer 500.

In example embodiments, conductive bumps 230 may be formed on chip pads 210 of the semiconductor chip 200, and the semiconductor chip 200 may be disposed such that a backside surface 204 opposite to a front surface 202 on which the chip pads 210 are formed, that is, an active surface faces the upper redistribution wiring layer 500. The semiconductor chip 200 may be disposed in a fan-in region of a carrier substrate C.

The conductive bump 230 may include a pillar bump formed on the chip pad 210 of the semiconductor chip 200 and a solder bump formed on the pillar bump. In some embodiments, the conductive bump 230 may include a solder bump formed on the chip pad 210 of the semiconductor chip 200.

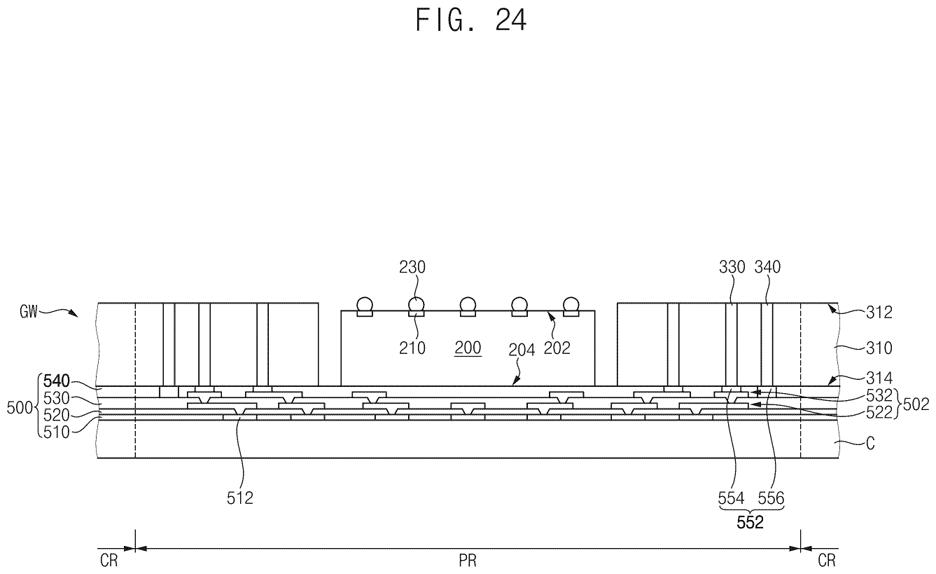

Referring to FIG. 24, processes the same as or similar to the processes described with reference to FIGS. 9 to 16 may be performed to dispose a glass frame GF on the upper redistribution wiring layer 500. The semiconductor chip 200 may be placed within a cavity 316 of the glass frame GF.

In example embodiments, the glass frame GF may be bonded to the upper redistribution wiring layer 500 through hybrid bonding. The semiconductor chip 200 may be spaced apart from an inner wall of the cavity 316. The front surface 202 of the semiconductor chip 200 on which the chip pads 210 are formed may be exposed from a first surface 312 of a glass substrate 310. The front surface 202 of the semiconductor chip 200 may be positioned lower than the first surface 312 of the glass frame GF. A thickness of the semiconductor chip 200 may be smaller than a thickness of the glass frame GF.

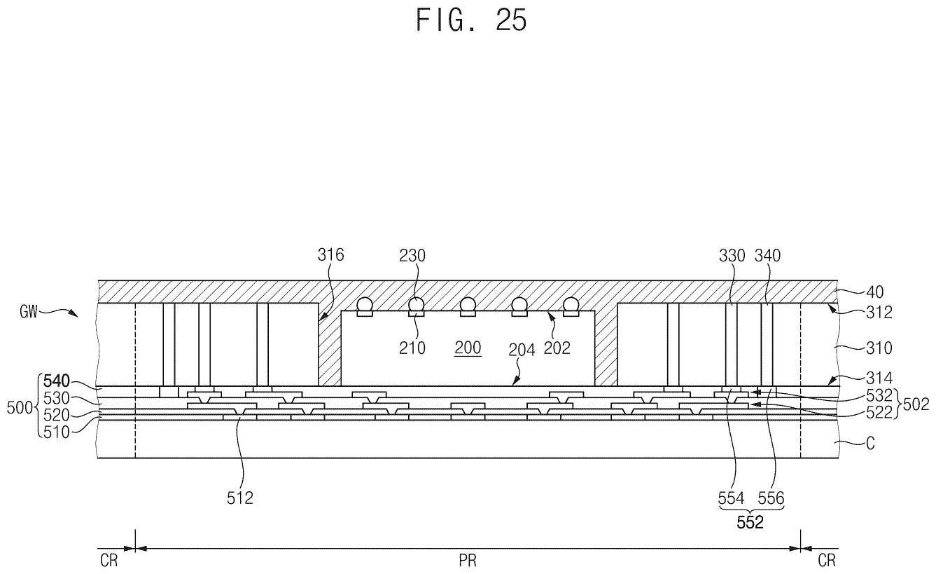

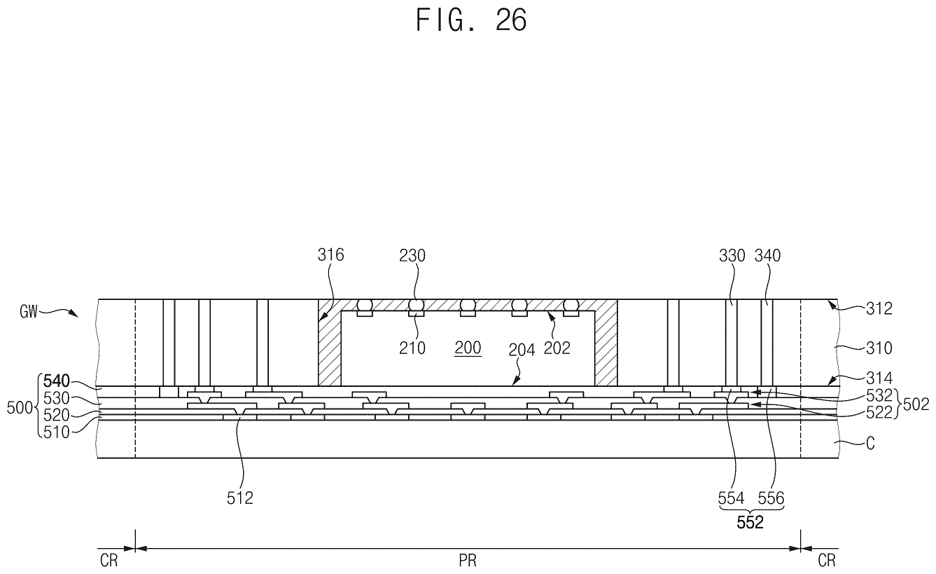

Referring to FIGS. 25 and 26, processes the same as or similar to the processes described with reference to FIGS. 17 and 18 may be performed to form a sealing material 40 on the first surface 312 of the glass frame GF to cover or overlap the semiconductor chip 200, and an upper portion of the sealing material 40 may be removed to form a sealing member 400 that exposes the conductive bumps 230 on the front surface 202 of the semiconductor chip 200.

In example embodiments, the upper portion of the sealing material 40 may be partially removed by a grinding process. As the upper portion of the sealing material 40 is removed, the conductive bumps 230 on the front surface 202 of the semiconductor chip 200 and the first surface 312 of the glass frame GF may be exposed by the sealing member 400. The sealing member 400 may include a first sealing portion 402 that covers, overlaps, or is on a side surface of the semiconductor chip 200 and a second sealing portion 404 that covers, overlaps, or is on the front surface 202 of the semiconductor chip 200. Upper surfaces of the conductive bumps 230 on the front surface 202 of the semiconductor chip 200 may be exposed by the second sealing portion 404 of the sealing member 400.

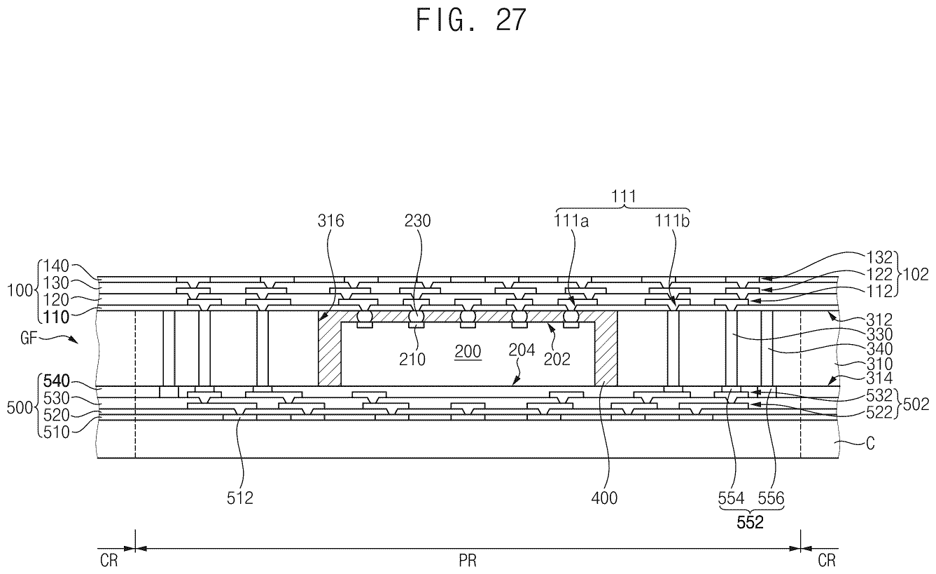

Referring to FIG. 27, processes the same as or similar to the processes described with reference to FIGS. 19 and 20 may be performed to form a lower redistribution wiring layer 100 having first redistribution wirings 102 electrically connected to a plurality of through vias 330 and the conductive bumps on the first surface 312 of the glass substrate GF.

Then, processes the same as or similar to the processes described with reference to FIG. 21 may be performed to form external connection members 160 each electrically connected to the first redistribution wirings 102 on an outer surface of the lower redistribution wiring layer 100, the carrier substrate C may be removed, and the glass frame GF may be separated into individual core substrates through a sawing process to complete the fan out package of semiconductor package 11 of FIG. 22.

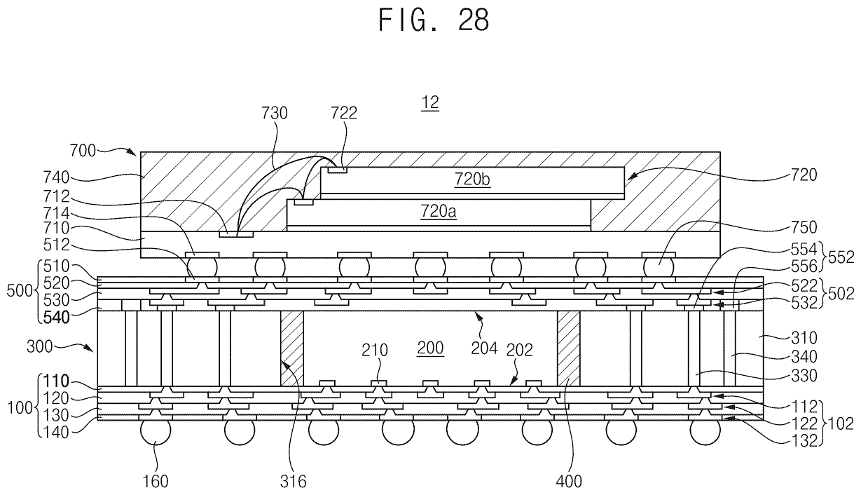

FIG. 28 is a cross-sectional view illustrating a semiconductor package in accordance with example embodiments. The semiconductor package is substantially the same as the semiconductor package described with reference to FIG. 1 except for an additional second package. Thus, same reference numerals may be used to refer to the same or like elements and any further repetitive explanation concerning the above elements will be omitted.

Referring to FIG. 28, a semiconductor package 12 may include a first package and a second package 700 stacked on the first package. The first package may include a lower redistribution wiring layer 100, a semiconductor chip 200, a core substrate 300, a sealing member 400, and an upper redistribution wiring layer 500. The first package may be substantially the same as or similar to the unit package or semiconductor package 10 described with reference to FIG. 1.

In example embodiments, the second package 700 may include a second package substrate 710, a plurality of second semiconductor chips 720 mounted on the second package substrate 710, and a sealing member 740 covering, overlapping, or on the second semiconductor chips 720 on the second package substrate 710.

The second package 700 may be stacked on the first package via conductive connection members 750. For example, the conductive connection members 750 may include solder balls, conductive bumps, etc. The conductive connection member 750 may be disposed between a first bonding pad 512 of the upper redistribution wiring layer 500 and a second connection pad 714 of the second package substrate 710. Accordingly, the first package and the second package 700 may be electrically connected to each other through conductive connection members 750.

The plurality of second semiconductor chips 720a and 720b may be sequentially stacked on the second package substrate 710 using adhesive members. Bonding wires 730 may connect second chip pads 722 of the second semiconductor chips 720 to first connection pads 712 of the second package substrate 710. The second semiconductor chips 720 may be electrically connected to the second package substrate 710 through the bonding wires 730.

The second semiconductor chips may include memory chips. The memory chip may include various types of memory circuits, such as DRAM, SRAM, flash, PRAM, ReRAM, FeRAM, or MRAM.

Although the second package 700 includes two semiconductor chips mounted using a wire bonding method, it will be understood that the number and mounting method of the semiconductor chips in the second package are not limited thereto.

In example embodiments, the semiconductor package 12 may further include a heat sink (not illustrated) stacked on the second package 700. The heat sink may be provided on the second package 700 and may dissipate heat from the first and second packages to the outside. The heat sink may be attached to the second package 700 using a thermal interface material (TIM).

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a lower redistribution wiring layer including first redistribution wirings;
a semiconductor chip on the lower redistribution wiring layer;
a core substrate on the lower redistribution wiring layer, the core substrate comprising a substrate having a cavity to accommodate the semiconductor chip, a plurality of through vias that extend into the substrate and electrically connect to ones of the first redistribution wirings, and a shielding structure that extends into the substrate and extends along an edge of the substrate;
a sealing member in a gap between an inner wall of the cavity of the substrate and the semiconductor chip; and
an upper redistribution wiring layer on the core substrate and including second redistribution wirings that are electrically connected to ones of the plurality of through vias.

2. The semiconductor package of claim 1, wherein the substrate includes a glass substrate.

3. The semiconductor package of claim 1, wherein the plurality of through vias and the shielding structure include a same metal.

4. The semiconductor package of claim 1, wherein the shielding structure has a rectangular closed loop shape that extends around the plurality of through vias in plan view.

5. The semiconductor package of claim 4, wherein the shielding structure includes four rounded corner portions.

6. The semiconductor package of claim 1, wherein a width of the shielding structure is within a range of 10 μm to 50 μm in a direction parallel to the substrate.

7. The semiconductor package of claim 1, wherein the sealing member is on side surfaces of the semiconductor chip, but does not overlap a backside surface of the semiconductor chip.

8. The semiconductor package of claim 1, wherein the upper redistribution wiring layer comprises:
a first upper insulating layer on an upper surface of the core substrate;
a first lower bonding pad in the first upper insulating layer and bonded to an end portion of one of the plurality of through vias; and
a second lower bonding pad in the first upper insulating layer and bonded to an end portion of the shielding structure.

9. The semiconductor package of claim 1, wherein a front surface of the semiconductor chip faces the lower redistribution wiring layer, and
wherein chip pads are on the front surface of the semiconductor chip.

10. The semiconductor package of claim 1, wherein the semiconductor chip comprises a first semiconductor chip, the semiconductor package further comprising:
a second package on the upper redistribution wiring layer,
wherein the second package includes a package substrate and a second semiconductor chip stacked on the package substrate.

11. A semiconductor package, comprising:
a core substrate having a first surface and a second surface opposite the first surface, the core substrate comprising a glass substrate having a cavity that extends from the first surface to the second surface, a plurality of through vias that extend into the glass substrate, and a shielding structure that extends into the glass substrate and extends along an edge of the glass substrate in plan view;
a semiconductor chip in the cavity of the core substrate, the semiconductor chip comprising chip pads on a front surface of the semiconductor chip, wherein the chip pads are separated from the first surface of the core substrate;
a lower redistribution wiring layer on the first surface of the core substrate and including first redistribution wirings electrically connected to the chip pads and the plurality of through vias; and
an upper redistribution wiring layer on the second surface of the core substrate and including second redistribution wirings electrically connected to the plurality of through vias.

12. The semiconductor package of claim 11, wherein the plurality of through vias and the shielding structure include a same metal.

13. The semiconductor package of claim 11, wherein the shielding structure has a rectangular closed loop shape that extends around the plurality of through vias in plan view.

14. The semiconductor package of claim 13, wherein the shielding structure includes four rounded corner portions.

15. The semiconductor package of claim 11, further comprising:
a sealing member in a gap between the semiconductor chip and an inner wall of the cavity of the glass substrate.

16. The semiconductor package of claim 15, wherein the sealing member is on side surfaces of the semiconductor chip, but does not overlap a backside surface of the semiconductor chip.

17. The semiconductor package of claim 11, wherein the lower redistribution wiring layer comprises:
a first lower insulating layer on the first surface of the core substrate; and
a first lower redistribution wiring on the first lower insulating layer and in direct contact with end portions of the chip pads and the plurality of through vias through first openings in the first lower insulating layer.

18. The semiconductor package of claim 11, wherein the upper redistribution wiring layer comprises:
a first upper insulating layer on the second surface of the core substrate;
a first lower bonding pad in the first upper insulating layer and bonded to an end portion of one of the plurality of through vias; and
a second lower bonding pad bonded to an end portion of the shielding structure.

19. The semiconductor package of claim 18, wherein the upper redistribution wiring layer further comprises:
first upper redistribution wirings on the first upper insulating layer and on the first lower bonding pad.

20. A semiconductor package, comprising:
a lower redistribution wiring layer including first redistribution wirings;
a core substrate on the lower redistribution wiring layer, the core substrate comprising a substrate having a cavity, a plurality of through vias that extend into the substrate and electrically connect to ones of the first redistribution wirings, and a shielding structure that extends into the substrate and extends along an edge of the substrate;
a semiconductor chip in the cavity of the core substrate on the lower redistribution wiring layer and having chip pads electrically connected to the first redistribution wirings;
a sealing member in a gap between the semiconductor chip and an inner wall of the cavity of the substrate; and
an upper redistribution wiring layer on the core substrate and including second redistribution wirings that are electrically connected to ones of the plurality of through vias.
